(19) United States
(12) Patent Application Publication
(10) Pub. No.: US 2022/0352070 A1
(43) Pub. Date: Nov. 3, 2022

(54) METAL FILAMENT VIAS FOR INTERCONNECT STRUCTURE

(71) Applicant: Taiwan Semiconductor Manufacturing Company, Ltd., Hsin-Chu (TW)

(72) Inventors: Mauricio Manfrini, Zhubei City (TW); Marcus Johannes Henricus van Dal, Linden (BE)

(21) Appl. No.: 17/866,924

(22) Filed: Jul. 18, 2022

Related U.S. Application Data
(62) Division of application No. 16/525,978, filed on Jul. 30, 2019.
(60) Provisional application No. 62/773,292, filed on Nov. 30, 2018.

(51) Int. Cl. H01L 23/522; H01L 21/768; H01L 23/532

(52) U.S. Cl. CPC H01L 23/5226; H01L 21/76816; H01L 23/53228

(57) ABSTRACT

The present disclosure relates to a method to form an integrated chip including a filament via. In some embodiments, a lower metal layer comprising a first metal line and a second metal line is formed over a substrate. A filament dielectric layer is formed over the lower metal layer. An upper metal layer comprising a first metal line and a second metal line is formed over the filament dielectric layer. A first contact is formed over the upper metal layer. A filament formation bias is applied through the first contact to form a first filament via through the filament dielectric layer and electrically connecting the first metal line of the lower metal layer and the first metal line of the upper metal layer.

### REFERENCE TO RELATED APPLICATIONS

This Application is a Divisional of U.S. application Ser. No. 16/525,978, filed on Jul. 30, 2019, which claims the benefit of U.S. Provisional Application No. 62/773,292, filed on Nov. 30, 2018. The contents of the above-referenced Patent Applications are hereby incorporated by reference in their entirety.

### BACKGROUND

Forming interconnect structures is usually complex and costly. It involves several processing modules of lithography, metallization and etching to form metal lines for lateral connections within a metal layer and metal vias for vertical connections between multiple metal layers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit comprising a filament via between two metal layers according to some embodiments.

FIG. 2 illustrates a cross-sectional view of an integrated circuit comprising a filament via between two metal layers according to some alternative embodiments.

FIGS. 3-4 illustrate cross-sectional views of an integrated chip comprising a filament via according to some embodiments.

FIG. 5 illustrates a cross-sectional view of an integrated circuit comprising filament vias between various metal layers according to some embodiments.

FIG. 6 illustrates a cross-sectional view of an integrated circuit, which comprises filament vias within different device regions and controlled by independent biases.

FIGS. 7-11 illustrate some embodiments of cross-sectional views showing a method of forming an IC comprising a filament via formed between metal layers of an interconnect structure.

FIG. 12 illustrates a flow diagram of a method of forming an integrated circuit comprising a filament vias between metal layers according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor industry has continually improved the processing capabilities and power consumption of integrated circuits (ICs) by shrinking the minimum feature size. As the semiconductor device size continues to scale down, the minimum feature size is reducing, which introduces challenges for photolithography because of the characteristics of the light (e.g. light diffraction), which also introduces difficulties for dielectric etching and metal filling. Also, it becomes more challenging to prevent metal diffusion and the resulting metal contamination during integration thermal cycles. The metal vias are badly affected because of the small dimensions. For example, the copper material used for connection may not be well formed in the via trench and thus may result in unreliable connections if not direct failure. The copper material may also diffuse into the neighbouring dielectric materials during the formation of the interconnect structure and when the formed interconnect structure is exposed to subsequent thermal processes. The diffused copper material may introduce metal contamination and electrical shortage.

In view of the above, some aspects of the present disclosure is related to a cost effective and performance reliable conductive via for an integrated chip and a formation method thereof. The metal via is formed utilizing the mechanism of metallic conductive filament formation occurring when applying a sufficient bias between two solid metal electrodes. In some embodiments, the filament via may be activated after other steps of forming the integration chip are finished, therefore making possible barrier-less Cu vias at scaled dimensions. Using the disclosed methods, ultra-scaled vias (e.g. down to 1 nm) can be achieved due to intrinsic character of filament formation mechanism. Thereby, the disclosed method of forming a filament via overcomes metal filling conformity issues faced by conventional vias such as vias formed by a damascene method. The disclosed method could be used to form filament via in distinct metal levels by applying specific bias conditions. The method of forming the metal via can be incorporated with readily available CMOS-compatible processes of the RRAM technology. The applied bias can be electrically controlled and programmable.

In some embodiments, the metal via can be formed permanently by applying a voltage large enough to form a stable metallic filament. In some other embodiments, the metal via could be formed and reversed during the operation of the integrated chip when specific metal levels need to be connected. A filament formation bias can be applied between the metal layers when the connection is sought and can be removed or replaced by a reset bias when the metal via needs to be removed. Specific metal levels, devices, regions of the chip could be turned-on by appropriate biasing schemes. In some embodiments, the existence of the metal via is programmable by electrically controlling the applying bias: the metallic filament is formed when applying the filament formation bias and is dissolved when applying zero-bias or the reset bias. Also, different biases can be used to form metallic filament with different widths. Thereby, a via wire resistance can be adjusted which allows resistance-capacitance optimization and can simplify the circuit periphery.

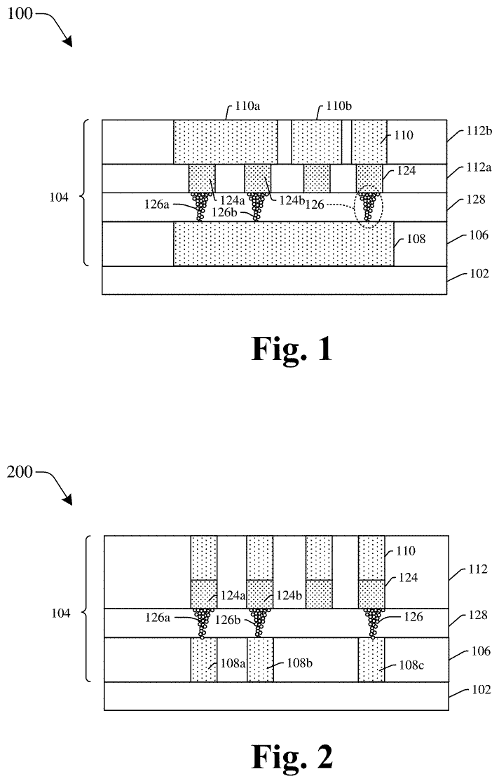

FIG. 1 shows a cross-sectional view 100 of an integrated circuit comprising a filament via 126 between a lower metal layer 108 and an upper metal layer 110 according to some embodiments. The lower metal layer 108 is disposed within a lower dielectric layer 106 over a substrate 102. In various embodiments, the substrate 102 may comprise a semiconductor body (e.g., monocrystalline silicon, SiGe, silicon-on-insulator (SOI)) such as a semiconductor wafer and/or one or more die on a wafer, as well as any other type of metal layer, device, semiconductor and/or epitaxial layers, etc., associated therewith. The lower metal layer 108 includes a plurality of metal lines that are configured to provide horizontal electrical connections. In various embodiments, the lower metal layer 108 may comprise copper, tungsten, and/or aluminum, for example. In some embodiments, one or more liner layers (not shown) may be deposited within the plurality of cavities prior to filling the plurality of cavities with the first conductive material. A filament dielectric layer 128 is disposed over the lower dielectric layer 106 and surrounded by a first portion of an upper dielectric layer 112a. In some embodiments, a filament metal layer 124 is disposed over the filament dielectric layer 128 and surrounded by a second portion of the upper dielectric layer 112b. An upper metal layer 110 is disposed over the filament metal layer 124. The upper metal layer 110 includes a plurality of metal lines (e.g. 110a, 110b) that are configured to provide horizontal electrical connections. The filament metal layer 124 includes a plurality of metal islands (e.g. 124a, 124b) corresponding to the filament vias 126 (e.g. 126a, 126b) and configured as a material source of the filament vias 126. In some embodiments, the filament metal layer 124 may have lateral dimensions (length and width) smaller than corresponding lateral dimensions of the upper metal layer 110. In some alternative embodiments, the filament metal layer 124 may have at least one lateral dimension (length or width) smaller than a corresponding lateral dimension (length or width) of the upper metal layer 110. The filament vias 126 have lateral dimensions (length and width) smaller than corresponding lateral dimensions of the filament metal layer 124. In various embodiments, the lower metal layer 108 and the upper metal layer 110 may comprise a conductive material such as platinum (Pt), aluminum-copper (AlCu), titanium nitride (TiN), gold (Au), titanium (Ti), tantalum (Ta), tantalum nitride (TaN), tungsten (W), tungsten nitride (WN), and/or copper (Cu), for example. In various embodiments, the filament dielectric layer 128 may be a dielectric material such as silicon dioxide, low-k dielectric material and ultra-low-k dielectric material. As an example, the filament dielectric layer 128 may have a thickness in a range of from about 1 nm to about 5 nm. In various embodiments, the filament metal layer 124 may comprises a conductive metal, such as copper, aluminum, silver, cobalt, tungsten, and/or alloys of these metals including ternary chalcogenides such as CuGeSe or CuGeTe. The filament metal layer 124 may be made of a material different than the upper metal layer 110. As an example, the filament metal layer 124 may have a thickness in a range of from about 5 nm to about 50 nm.

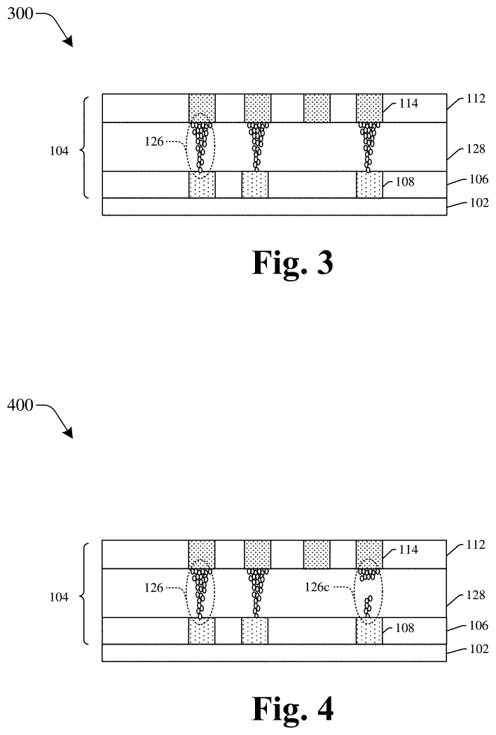

FIG. 2 illustrates a cross-sectional view 200 of an integrated circuit comprising a filament via 126 between two metal layers 108, 110 according to some alternative embodiments. Compared to the integrated circuit shown in FIG. 1, in some alternative embodiments, the filament metal layer 124 may have its sidewalls vertically aligned with sidewalls of the upper metal layer 110. The filament vias 126 are established within the filament dielectric layer 128 at positions where the filament metal layer 124 and the lower metal layer 108 vertically cross one another. For example, a first filament via 126a is disposed vertically between a first portion 124a of the filament metal layer 124 and a first portion 108a of the lower metal layer 108, and a second filament via 126b is disposed vertically between a second portion 124b of the filament metal layer 124 and a second portion 108b of the lower metal layer 108. In some embodiments, the filament vias 126 shown in various figures can be formed permanently and not reversible by applying a bias large enough to form a stable metallic filament. The bias is greater than a breakdown voltage of the first filament via 126a. Applying a bias greater than a breakdown voltage of the metallic filament would damage the device and frustrate the purpose of the device for a resistive memory device or other devices utilizing a switching mechanism based on the establish and breaking of a conductive filament. However, the disclosed approach is to form a conductive via for the interconnect structure, and thus the reverse of the conductive filament is not required. In some other embodiments, the filament vias 126 could be formed and reversed during the operation of the integrated chip when specific metal levels need to be connected.

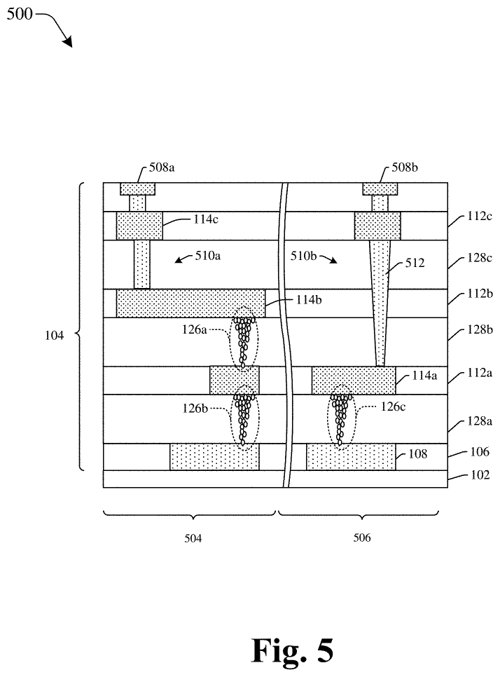

FIGS. 3-4 illustrate cross-sectional views 300, 400 of an integrated chip comprising a filament via according to some embodiments. In some alternative embodiments, the functions of the filament metal layer 124 and the upper metal layer 110 shown and described with reference to FIG. 1 and FIG. 2 may be performed by a metal layer 114 made of one single material. The filament vias 126 may have a wider portion directly contacts metal layer 114 and a narrower portion directly contacts a lower metal layer 108. The metal layer 114 may comprises a conductive metal, such as copper, aluminium, silver, cobalt, tungsten, and/or alloys of these metals including ternary chalcogenides such as CuGeSe or CuGeTe. As shown by FIG. 3, during an operation of the integrated chip, a filament formation bias can be applied between the metal layers 108 and 114 when the connection is sought. The filament vias 126 are established vertically between corresponding portions of the metal layers 108 and 114. As shown by FIG. 4, during an operation of the integrated chip, a reset bias can be applied between the metal layers 108 and 114 when the filament vias 126 need to be removed. The filament vias 126 are broken and leaving metal dots residues (e.g. 126c) of the clusters of the filament vias disconnected by the filament dielectric layer 128 between corresponding portions of the metal layers 108 and 114. In some embodiments, filament vias can be controlled independently, individually or by device regions. Specific filament via can be established and broken according to the bias applied. In some embodiments, the existence of the metal via is programmable by electrically controlling the applying bias: the metallic filament is formed when applying the filament formation bias and is dissolved when applying zero-bias or the reset bias.

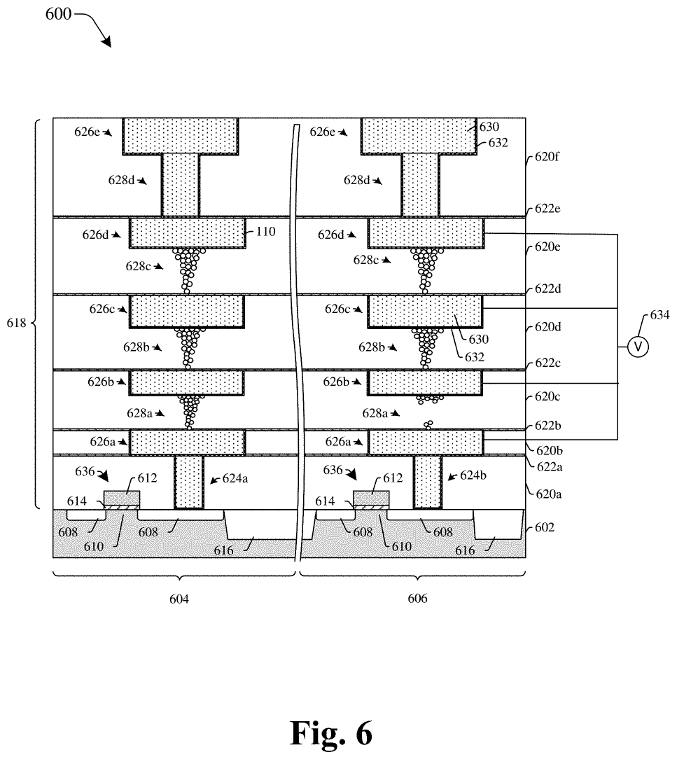

FIG. 5 shows a cross-sectional view 500 of an integrated circuit comprising filament vias (e.g. 126a, 126b, 126c) between various metal layers (e.g. 108, 114a, 114b, 114c) according to some embodiments. Connect structures 510a, 510b are disposed within the interconnect structure 104 respectively coupling corresponding filament vias 126a 126c to contacts 508a, 508b to provide access to activate the filaments vias 126a, 126c independently for different device regions 504, 506 or different metal layers. In some embodiments, the connect structure 510a may comprise staggered metal lines and vias. In some other embodiments, the connect structure 510b may comprise a supervia 512 that crosses more than one interlayer dielectric layers 128b, 128c, and disposed through at least one surrounding dielectric layer 112b of a metal layer 114b. The existence of the metal via may be programmable by electrically controlling the biases applied through the contacts 508a, 508b. The metallic filament is formed when applying the filament formation bias and is dissolved when applying zero-bias or the reset bias. Also, different biases can be used to form metallic filament with different widths. Thereby, a via wire resistance can be adjusted which allows for resistance-capacitance optimization and can simplify the circuit periphery.

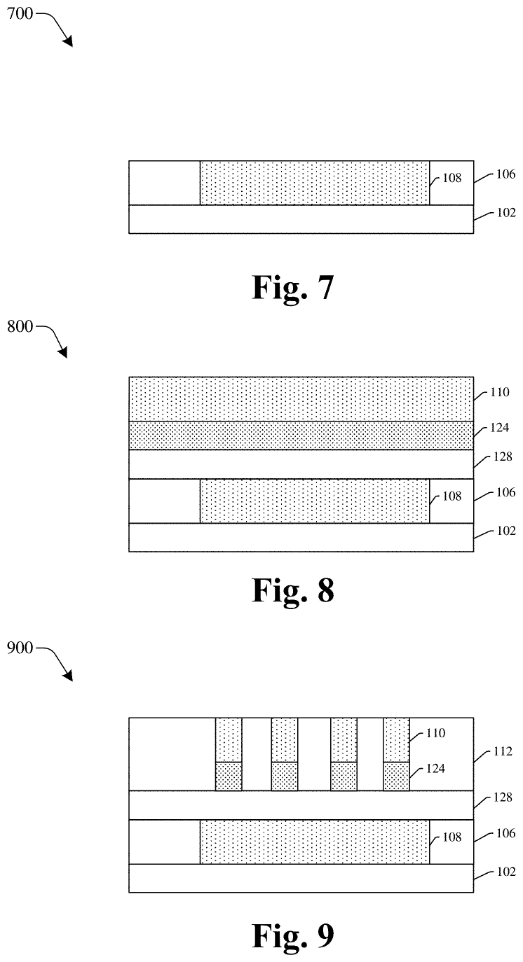

FIG. 6 illustrates a cross-sectional view of some additional embodiments of an integrated chip 600 that includes a substrate 602. The integrated chip comprises a first device region 604 and a second device region 606. The first device region 604 and the second device region 606 may be a memory region, a logic region, or other function regions.

Transistors 636 are shown in the first device region 604 and the second device region 606 as an example, but other active devices can also be arranged in or over the substrate and coupled to the disclosed filament vias. As shown in the figure, the transistor 636 in either the first device region 604 or the second device region 606 includes source/drain regions 608 that are separated by a channel region 610. A gate electrode 612 overlies the channel region 610, and is separated from the channel region 610 by a gate dielectric 614. Isolation structures 616 (e.g., shallow trench isolation structures) may be arranged in the substrate 602 to provide isolation between neighboring transistor devices.

A back-end-of-line (BEOL) interconnect structure 618 is disposed over the substrate 602, and operable couples the transistors to one another. The BEOL interconnect structure 618 includes a dielectric structure with a plurality of conductive features disposed within the dielectric structure. The dielectric structure may comprise a plurality of stacked inter-level dielectric (ILD) layers 620a-620f. In various embodiments, the plurality of ILD layers 620a-620f may comprise one or more dielectric materials, such as a low-k dielectric material or an ultra-low-k (ULK) dielectric material, for example. In some embodiments, the one or more dielectric materials may comprise SiO₂, SiCO, a fluorosilicate glass, a phosphate glass (e.g., borophosphate silicate glass), etc. In some embodiments, etch stop layers (ESLs) 622a-622f may be disposed between adjacent ones of the ILD layers 620a-620f. For example, a first ESL 622a is disposed between a first ILD layer 620a and a second ILD layer 620b, a second ESL 622b is disposed between the second ILD layer 620b and a third ILD layer 620c, etc. In various embodiments, the ESLs 622a-622e may comprise a nitride, silicon carbide, carbon-doped oxide, or other similar materials.

A first conductive contact 624a and a second conductive contact 624b are arranged within the first ILD layer 620a. The first conductive contact 624a is electrically connected to a source/drain region of a transistor device in the first device region 604, and the second conductive contact 624b is electrically connected to source/drain region of a transistor device in the second device region 606. In various embodiments, the first conductive contact 624a and the second conductive contact 624b may be connected to a source region, a drain region, or a gate electrode of a transistor in the memory region or logic region. In some embodiments, the first conductive contact 624a and the second conductive contact 624b may comprise tungsten, for example.

Alternating layers of metal layers 626a-626e and metal vias 628a-628d are disposed over the first conductive contact 624a and the second conductive contact 624b. The metal layers 626a-626e comprise a conductive material. In some embodiments, the metal layers 626a-626e comprise a conductive core 630 and a liner layer 632 that separates the conductive core from surrounding ILD layers. In some embodiments, the liner layer may comprise titanium (Ti), titanium nitride (TiN), tantalum (Ta), or tantalum nitride (TaN). In some embodiments, the conductive core may comprise copper and/or aluminum, for example.

In some embodiments, at least some of the metal vias 628a-628d are filament vias comprising clusters of metal dots consisting conductive metal filaments. The filament vias may be in direct contact with the ILD layers 620a-620f. In comparison, some other metal vias (e.g. 628d shown in FIG. 6 as an example) may be separated from the ILD layers 620a-620f by the liner layer 632, which may function as a barrier layer to prevent the metal vias (e.g. 628d) from diffusing into the ILD layers 620a-620f. In some embodiments, a filament metal layer (e.g. similar to the filament metal layer 124 shown in FIG. 1 or FIG. 2) is inserted between the metal layers 626a-626e and the filament vias. The filament vias may be inserted between multiple metal layers, for example, a first filament via 628a between the first metal layer 626a and the second metal layer 626b, a second filament via 628b between the second metal layer 626b and the third metal layer 626c, and/or a third filament via 628c between the third metal layer 626c and the fourth metal layer 626d. The first filament via 628a, the second filament via 628b, and the third filament via 628c may have different heights or width. In some embodiments, the filament vias may be controlled by a bias source 634 connected to the corresponding metal layers, and can be established and reset depending on the bias applied. For example, during the operation of the integrated chip 600, the filament vias 628a, 628b, and 628c may be established in the first device region 604 and the second device region 606 by applying set biases to the corresponding metal layers. A reset bias can be applied to one device region (e.g. the second device region 606) and break a filament via (e.g. the first filament via 628a in the second device region), while some other filament vias remain established. In some alternative embodiments, the filament vias may be permanent. The filament vias may be activated after the manufacture of the integrated chip 600 by applying establishing biases. The filament vias may not be reversible.

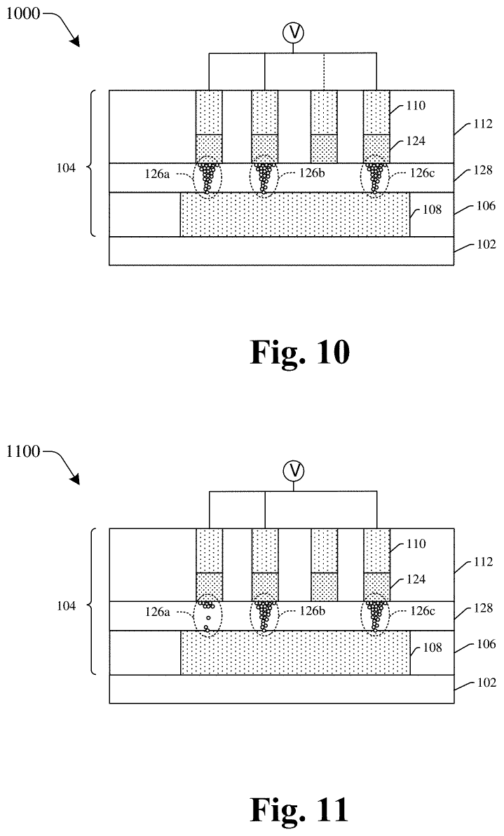

FIGS. 7-11 illustrate some embodiments of cross-sectional views 700-1100 showing a method of forming an IC comprising a filament via. Although the cross-sectional-views shown in FIGS. 7-11 are described with reference to a method of forming a filament via, it will be appreciated that the structures shown in the figures are not limited to the method of formation but rather may stand alone separate of the method.

As illustrated in cross-sectional view 700 of FIG. 7, a lower metal layer 108 is formed within a lower dielectric layer 106 over a substrate 102. In various embodiments, the substrate 102 may comprise a semiconductor body (e.g., monocrystalline silicon, SiGe, silicon-on-insulator (SOI)) such as a semiconductor wafer and/or one or more die on a wafer, as well as any other type of metal layer, device, semiconductor and/or epitaxial layers, etc., associated therewith. The lower dielectric layer 106 is selectively etched to define a plurality of cavities within the lower dielectric layer 106. The plurality of cavities are filled with a first conductive material to establish the lower metal layer 108. In various embodiments, the first conductive material may comprise copper, tungsten, and/or aluminum, for example. In some embodiments, the first conductive material may be deposited by way of a plating process (e.g., an electro plating process, an electro-less plating process). In other embodiments, the first conductive material may be deposited using a vapor deposition technique (e.g., CVD, PVD, ALD, PE-ALD, etc.). In some embodiments, one or more liner layers (not shown) may be deposited within the plurality of cavities prior to filling the plurality of cavities with the first conductive material.

As illustrated in cross-sectional view 800 of FIG. 8, a filament dielectric layer 128 is formed over the lower dielectric layer 106. An upper metal layer 110 is formed over the filament dielectric layer 128. In some embodiments, a filament metal layer 124 is formed between the upper metal layer 110 and the filament dielectric layer 128. In various embodiments, the lower metal layer 108, the filament dielectric layer 128, the filament metal layer 124, and the upper metal layer 110 may be deposited in-situ or ex-situ using vapor deposition techniques (e.g., CVD, PVD, ALD, PE-ALD, etc.). The filament metal layer 124 and the filament dielectric layer 128 are deposited without air brake to enhance interface quality for filament formation. In various embodiments the lower metal layer 108 and the upper metal layer 110 are made of a metal, and are formed by sputtering, electroplating, electroless plating, or a vapor deposition technique, for example. In various embodiments, the lower metal layer 108 and the upper metal layer 110 may comprise a conductive material such as platinum (Pt), aluminum-copper (AlCu), titanium nitride (TiN), gold (Au), titanium (Ti), tantalum (Ta), tantalum nitride (TaN), tungsten (W), tungsten nitride (WN), and/or copper (Cu), for example. In various embodiments, the filament dielectric layer 128 may be a dielectric material such as silicon dioxide, low-k dielectric material and ultra-low-k dielectric material. As an example, the filament dielectric layer 128 may have a thickness in a range of from about 1 nm to about 5 nm. Examples of the dielectric material comprise nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), and/or copper oxide (CuO), for example. In various embodiments, the filament metal layer 124 may comprises a conductive metal, such as copper, aluminum, silver, cobalt, tungsten, and/or alloys of these metals including ternary chalcogenides such as CuGeSe or CuGeTe. As an example, the filament metal layer 124 may have a thickness in a range of from about 5 nm to about 50 nm.

As illustrated in cross-sectional view 900 of FIG. 9, the upper metal layer 110 and the filament metal layer 124 are patterned to define discrete portions. In some embodiments, the upper metal layer 110 and the filament metal layer 124 are patterned using one mask and thus have sidewalls aligned with one another. In some alternative embodiments, such as shown by FIG. 1, the upper metal layer 110 and the filament metal layer 124 are patterned separately using different masks. The filament metal layer 124 defines locations where filament vias are designed. Comparing to previous via patterning and forming technology, the patterning of the filament metal layer 124 can be achieved with more relaxed (non-critical) lithography technologies, since the size of the via will be determined by the filament width which can be smaller than the lithography feature size. Various patterning techniques can be used for a dense via patterning, such as self-aligned double patterning (SADP), self-aligned quadruple patterning (SAQP), and/or extreme ultraviolet (EUV) lithography. The fabrication process is continued, and various manufacturing steps are performed to form an integrated chip. Among other steps, an upper dielectric layer 112 may be formed surrounding the filament metal layer 124 and the upper metal layer 110. Though not shown in FIG. 9, more metal layers may be stacked over the lower metal layer 108 and the upper metal layer 110 as a part of a back-end-of line (BEOL) interconnect structure. More layers of the filament metal layers and the filament dielectric layers may be inserted in the metal layers, similar as the filament dielectric layer 128 and the filament metal layer 124 inserted between the lower metal layer 108 and the upper metal layer 110. The metal layers and the filament dielectric layers may have different heights.

As illustrated in cross-sectional view 1000 of FIG. 10, filament vias 126a, 126b, and 126c are activated by applying biases. In some embodiments, the activation of the filament vias are performed after the CMOS process is finalized. For example, the bias is applied using a tool of the wafer acceptance test, and just prior to the wafer acceptance test. Different biases may be applied independently to activate filament vias located between different metal layers. The biases can be chosen to form the filament vias of certain resistances. The biases applied may be large enough that the formed filament vias are permanent and not reversible. In some embodiments, a controller and a multiplexers may be used to control the bias at specific locations or different metal layers.

As illustrated in cross-sectional view 1100 of FIG. 11, in some alternative embodiments, during the operation of the integrated chip, the formation of the filament vias are reversible by applying a reset bias. The filament via 126a may be broken when a reset bias is applied to the upper metal layer 110 and the lower metal layer 108. The broken filament via 126a may have residues of a cluster of metal dots separated by the filament dielectric layer 128. The filament vias can be programmable.

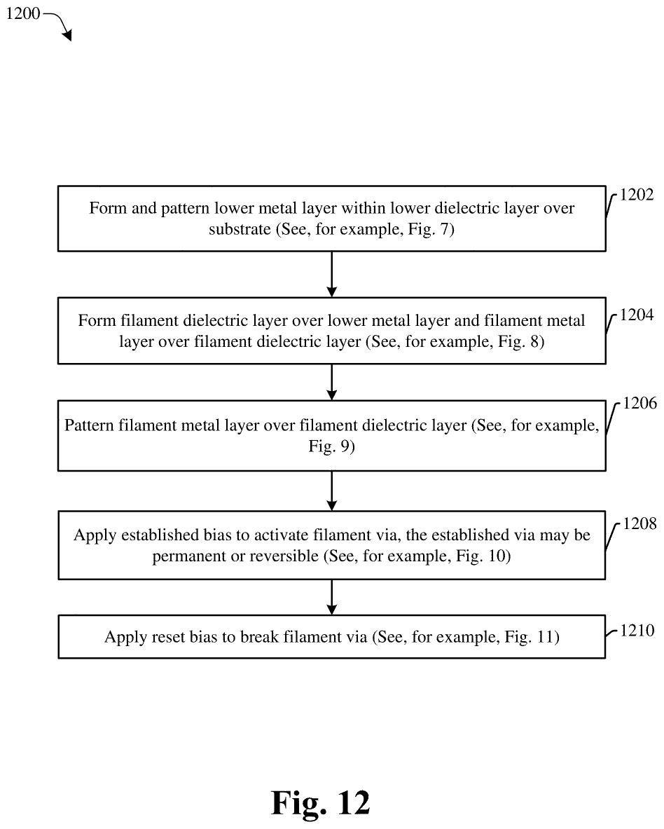

FIG. 12 illustrates a flow diagram of some embodiments of a method 1200 of forming an IC comprising a filament via.

While disclosed methods (e.g., methods 1200) are illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases

At act 1202, a lower metal layer is formed and patterned within a lower dielectric layer over a substrate. The lower dielectric layer is selectively etched to define a plurality of cavities within the lower dielectric layer and filled with a first conductive material to establish a plurality of lower metal lines. FIG. 7 illustrates some embodiments of a cross-sectional view 700 corresponding to act 1202.

At act 1204, a filament dielectric layer is formed over the lower dielectric layer and the lower metal layer. The filament dielectric layer may be formed across the interconnect structure and configured as an interlayer dielectric layer immediately above the lower metal layer. In various embodiments, the filament dielectric layer may be a dielectric material such as silicon dioxide, low-k dielectric material and ultra-low-k dielectric material. As an example, the filament dielectric layer may have a thickness in a range of from about 1 nm to about 5 nm. A filament metal layer is formed over the filament dielectric layer. FIG. 8 illustrates some embodiments of the cross-sectional view 800 corresponding to act 1204.

At act 1206, the filament metal layer may be patterned to form a plurality of discrete islands corresponding to the filament vias to be formed. In some embodiments, a separate upper metal layer may also be formed over the filament layer. The upper metal layer may include a plurality of upper metal lines. In some alternative embodiments, the upper metal layer may be omitted and the filament metal layer serves as a metal layer for the interconnect structure. In various embodiments the lower metal layer 108 and the upper metal layer 110 are made of a metal, and are formed by sputtering, electroplating, electroless plating, or a vapor deposition technique, for example. In various embodiments, the filament metal layer 124 may comprises a conductive metal, such as copper, aluminum, silver, cobalt, tungsten, and/or alloys of these metals including ternary chalcogenides such as CuGeSe or CuGeTe. As an example, the filament metal layer 124 may have a thickness in a range of from about 5 nm to about 50 nm. FIG. 9 illustrates some embodiments of a cross-sectional view 900 corresponding to act 1206.

At act 1208, filament vias are established by applying biases. In some embodiments, the activation of the filament vias are performed after the CMOS process is finalized. For example, the bias is applied using a tool of the wafer acceptance test, and just prior to the wafer acceptance test. Different biases may be applied independently to activate filament vias located between different metal layers. The biases can be chosen to form the filament vias of certain resistances. The biases applied may be large enough that the formed filament vias are permanent and not reversible. The biases applied may also be chosen such that the formed filament vias are reversible when a reset bias is applied. In some embodiments, a controller and a multiplexers may be used to control the bias at specific locations or different metal layers. FIG. 10 illustrates some embodiments of a cross-sectional view 1000 corresponding to act 1208.

At act 1210, in some embodiments, during the operation of the integrated chip, the formation of the filament vias can be reversed by applying a reset bias. The filament via may be broken when a reset bias is applied. The broken filament via may have residues of a cluster of metal dots separated by the filament dielectric layer. The filament vias can be programmable. FIG. 11 illustrates some embodiments of a cross-sectional view 1100 corresponding to act 1210.

Thus, as can be appreciated from above, the present disclosure relates to an interconnect structure of an integrated chip with a filament via and associated methods. The filament via may be established between two metal layers of the interconnect structure after other steps of forming the integration chip are finished, therefore making possible barrier-less Cu vias at scaled dimensions. Using the disclosed methods, ultra-scaled vias (e.g. down to 1 nm) can be achieved due to intrinsic character of filament formation mechanism.

In some embodiments, the present disclosure relates a method to form an interconnect structure of an integrated chip. In the method, a lower metal layer comprising a first metal line and a second metal line is formed over a substrate. A filament dielectric layer is formed over the lower metal layer. An upper metal layer comprising a first metal line and a second metal line is formed over the filament dielectric layer. A first contact is formed over the upper metal layer. A filament formation bias is applied through the first contact to form a first filament via through the filament dielectric layer and electrically connecting the first metal line of the lower metal layer and the first metal line of the upper metal layer.

In other embodiments, the present disclosure relates to a method of forming an integrated chip including an interconnect structure. The method comprises forming a first metal layer, a first filament dielectric layer, a first filament metal layer, and a second metal layer one stacked over another. The method further comprises patterning the second metal layer and the first filament metal layer to form discrete portions. The method further comprises applying a first bias between the second metal layer and the first metal layer and forming a first filament via through the first filament dielectric layer between the first filament metal layer and the first metal layer.

In yet other embodiments, the present disclosure relates to a method of forming an integrated chip including an interconnect structure. The method comprises forming a first metal layer over a substrate and forming a first filament dielectric layer over the first metal layer. The method further comprises forming a second metal layer over the first filament dielectric layer and forming a second filament dielectric layer over the second metal layer. The method further comprises forming a third metal layer over the second filament dielectric layer. The method further comprises by applying a filament formation bias, forming a first filament via through the first filament dielectric layer and connecting the first metal layer and the second metal layer and a second filament via through the second filament dielectric layer and connecting the second metal layer and the third metal layer. The second filament via has a height greater than that of the first filament via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method to form an interconnect structure of an integrated chip, the method comprising:
forming a lower metal layer comprising a first metal line and a second metal line over a substrate;
forming a filament dielectric layer over the lower metal layer;
forming an upper metal layer comprising a first metal line and a second metal line over the filament dielectric layer;
forming a first contact over the upper metal layer; and
applying a filament formation bias through the first contact to form a first filament via through the filament dielectric layer and electrically connecting the first metal line of the lower metal layer and the first metal line of the upper metal layer.

2. The method of claim 1, further comprising:
applying a filament removal bias through the first contact to at least partially remove the first filament via from the filament dielectric layer and disconnect the first metal line of the lower metal layer and the first metal line of the upper metal layer.

3. The method of claim 1, further comprising:
forming a second contact over the upper metal layer and electrically separated from the first contact; and
applying the filament formation bias through the second contact to form a second filament via through the filament dielectric layer and electrically connecting the second metal line of the lower metal layer and the second metal line of the upper metal layer;
wherein the first filament via and the second filament via are configured to be formed separately.

4. The method of claim 3, wherein the first filament via and the second filament via are configured to be removed separately by applying a filament removal bias to the first contact or the second contact.

5. The method of claim 1, wherein the lower metal layer and the upper metal layer are made of copper.

6. The method of claim 1, further comprising forming a filament metal layer between and directly contacting the filament dielectric layer and the upper metal layer.

7. The method of claim 6, wherein the filament metal layer is made of metal chalcogenide.

8. The method of claim 6, wherein the filament metal layer has sidewalls vertically aligned with sidewalls of the upper metal layer.

9. The method of claim 6, wherein the filament metal layer is made of a plurality of discrete islands comprising a first island configured as a material source of the first filament via and a second island configured as a material source of a second filament via.

10. The method of claim 1, wherein the first filament via is formed contacting the first metal line of the lower metal layer.

11. A method of forming an integrated chip including an interconnect structure, the method comprising:
forming a first metal layer, a first filament dielectric layer, a first filament metal layer, and a second metal layer one stacked over another;
patterning the second metal layer and the first filament metal layer to form discrete portions respectively; and
applying a first bias between the second metal layer and the first metal layer and forming a first filament via through the first filament dielectric layer between the first filament metal layer and the first metal layer.

12. The method of claim 11, wherein the second metal layer and the first filament metal layer are patterned to have sidewalls vertically aligned one another.

13. The method of claim 11, further comprising:
forming a second filament dielectric layer, a second filament metal layer, and a third metal layer in that order over the second metal layer; and
applying a second bias between the third metal layer and the second metal layer and forming a second filament via through the second filament dielectric layer between the second filament metal layer and the second metal layer;
wherein the second bias is greater than the first bias.

14. The method of claim 11, wherein the first bias is greater than a breakdown voltage of the first filament via, and the first filament via is permanent.

15. The method of claim 11,
wherein the second metal layer is patterned to form a plurality of metal lines configured to provide horizontal electrical connection; and
wherein the first filament metal layer is patterned to form a plurality of discrete islands configured as a material source of filament vias.

16. A method to form an interconnect structure of an integrated chip, the method comprising:
forming a first metal layer over a substrate;
forming a first filament dielectric layer over the first metal layer;
forming a second metal layer over the first filament dielectric layer;
forming a second filament dielectric layer over the second metal layer;
forming a third metal layer over the second filament dielectric layer; and
by applying a filament formation bias, forming a first filament via through the first filament dielectric layer and connecting the first metal layer and the second metal layer and a second filament via through the second filament dielectric layer and connecting the second metal layer and the third metal layer;
wherein the second filament via has a height greater than that of the first filament via.

17. The method of claim 16, further comprising forming a first contact on top of the integrated chip for applying the filament formation bias and forming the first filament via and the second filament via.

18. The method of claim 17, further comprising applying a filament removal bias to at least partially remove one or both of the first filament via and the second filament via.

19. The method of claim 16, wherein the first filament via and the second filament via are formed permanently and not reversible.

20. The method of claim 16, wherein the first filament via is formed directly contacting the first metal layer.
